(19) United States
(12) Patent Application Publication
(10) Pub. No.: US 2007/0134817 A1
(43) Pub. Date: Jun. 14, 2007

(54) Method for Manufacturing Ferroelectric Memory

(75) Inventor: Takafumi NODA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/549,292

(22) Filed: Oct. 13, 2006

(30) Foreign Application Priority Data
Nov. 29, 2005 (JP) 2005-343343

(51) Int. Cl. H01L 21/00

(52) U.S. Cl. 438/3

(57) ABSTRACT

A method for manufacturing a ferroelectric memory includes the steps of forming a driving transistor on a semiconductor substrate, forming a first interlayer dielectric film that covers the driving transistor on the semiconductor substrate, forming a first hydrogen barrier film on the first interlayer dielectric film, and forming a ferroelectric capacitor electrically connected to the driving transistor on the first hydrogen barrier film, wherein hydrogen sintering treatment is conducted between the step of forming the driving transistor and the step of forming the first hydrogen barrier film.

The entire disclosure of Japanese Patent Application No. 2005-343343, filed Nov. 29, 2005 is expressly incorporated by reference herein.

### BACKGROUND

1. Technical Field

The present invention relates to a method for manufacturing a ferroelectric memory having a ferroelectric capacitor.

2. Related Art

A ferroelectric memory, for example, a ITIC type ferroelectric memory is equipped with a ferroelectric capacitor and a driving transistor for driving the ferroelectric capacitor. In general, in the process of manufacturing ferroelectric capacitors, it is an important task to prevent deterioration of ferroelectric layers. More specifically, in the process of manufacturing a ferroelectric capacitor, after a ferroelectric layer is formed, the ferroelectric layer may be exposed to a hydrogen atmosphere (i.e., a reducing atmosphere) in the steps of forming an interlayer dielectric film, dry-etching and the like. When the ferroelectric layer is exposed to a reducing atmosphere, for example, hydrogen (H₂), water (H₂O) and the like, oxygen that composes the ferroelectric layer is reduced because the ferroelectric layer is generally composed of metal oxide, such that electrical characteristics of the ferroelectric capacitor would considerably be deteriorated.

Accordingly, as a measure to prevent hydrogen damage, areas around the ferroelectric capacitor may be covered by a hydrogen barrier film (SiN, Al₂O₃ or the like). For example, when a ferroelectric capacitor is provided on a first interlayer dielectric film on a semiconductor substrate on which a driving transistor is formed, a hydrogen barrier film is provided on the ferroelectric capacitor to cover the upper surface of the ferroelectric capacitor and on the first interlayer dielectric film that is located below the ferroelectric capacitor.

On the other hand, in the manufacturing of the driving transistor, in order to stabilize (reduce) the interface state in the gate dielectric film and stabilize (reduce) the wiring resistance, hydrogen sintering treatment is generally conducted after the steps of forming the driving transistor and wiring, in other words, in the final step in the semiconductor preprocessing (after a passivation film is formed).

However, when areas around the ferroelectric capacitor are covered by the hydrogen barrier film as described above, the hydrogen sintering treatment in the final step would not effectively act on the driving transistor due to the function of the hydrogen barrier film, which causes a problem in particular in that the interface state in the gate dielectric film would not sufficiently be reduced.

Because of the reasons described above, technologies have been provided to improve ferroelectric films (ferroelectric layers) so that the films would be difficult to deteriorate by hydrogen. In this respect, an example of related art is described in Japanese Laid-open Patent Application JP-A-2002-124647.

However, even when ferroelectric films per se are improved so as to be resistive to deterioration by hydrogen, it is very difficult to completely prevent deterioration. For example, the aforementioned document describes prevention of deterioration of ferroelectric films, but hardly discusses sintering effects on transistors, and therefore may not give sufficient consideration to the reliability of transistors.

### SUMMARY

In accordance with an advantage of some aspects of the present invention, it is possible to provide a method for manufacturing a ferroelectric memory, which can achieve both prevention of deterioration of ferroelectric layers and desired effects of hydrogen sintering treatment on transistors.

A method for manufacturing a ferroelectric memory includes the steps of: forming a driving transistor on a semiconductor substrate, forming a first interlayer dielectric film on the semiconductor substrate to cover the driving transistor, forming a first hydrogen barrier film on the first interlayer dielectric film, and forming a ferroelectric capacitor electrically connected to the driving transistor on the first hydrogen barrier film, wherein hydrogen sintering treatment is conducted between the step of forming the driving transistor and the step of forming the first hydrogen barrier film.

According to the method for forming a ferroelectric memory described above, after the driving transistor has been formed, hydrogen sintering treatment is conducted prior to forming the first hydrogen barrier film, such that the hydrogen sintering treatment can be applied to the driving transistor without being influenced by the hydrogen barrier film, and therefore the interface state in the gate oxide film can be stabilized (reduced).

In the method for forming a ferroelectric memory described above, the hydrogen sintering treatment may preferably be conducted after the step of forming the first interlayer dielectric film.

When hydrogen sintering treatment is directly applied to the driving transistor, there is a possibility of negatively affecting a semiconductor region composing the driving transistor, for example, impurity regions such as source/drain regions. However, by conducting the hydrogen sintering treatment after forming the first interlayer dielectric film, the possibility can be reduced. In other words, by applying the hydrogen sintering treatment indirectly to the driving transistor through the first interlayer dielectric film, hydrogen existing in the first interlayer dielectric film is excited, and the hydrogen can be made to act on the driving transistor, whereby the effects on the gate dielectric film can be maintained, and negative effects on the semiconductor regions can be reduced.

Also, the method for manufacturing a ferroelectric memory may preferably have, after the step of forming the ferroelectric capacitor, the steps of forming a second hydrogen barrier film that covers the ferroelectric capacitor, forming a second interlayer dielectric film on the second hydrogen barrier film, forming, on the second interlayer dielectric film, a wiring that conductively connects to the ferroelectric capacitor through a plug, and conducting hydrogen sintering treatment after the step of forming the wiring.

As a result, conditions of the interface between the plug and the wiring can be made better by the hydrogen sintering treatment, and the contact resistance can be reduced. Also, the second hydrogen barrier film is formed in a manner to cover the ferroelectric capacitor, such that the effects of the hydrogen sintering treatment can be prevented from reaching the ferroelectric capacitor.

Furthermore, the method for manufacturing a ferroelectric memory may preferably have, after the step of forming the ferroelectric capacitor, the step of forming a second interlayer dielectric film that covers the ferroelectric capacitor and has hydrogen concentration lower than that of the first interlayer dielectric film.

As a result, influences on the ferroelectric layer in the ferroelectric capacitor, which may be caused by hydrogen in the second interlayer dielectric film, can be reduced, and therefore the reliability of the ferroelectric capacitor can be improved.

### BRIEF DESCRIPTION OF THE DRAWINGS

FIG. 1 is a cross-sectional view of a main portion of a ferroelectric memory in accordance with an embodiment of the invention.

FIGS. 2A-2C are views for describing steps of a method for manufacturing the ferroelectric memory shown in FIG. 1.

FIGS. 3A-3C are views for describing steps of the method for manufacturing the ferroelectric memory shown in FIG. 1.

FIGS. 4A and 4B are views for describing steps of the method for manufacturing the ferroelectric memory shown in FIG. 1.

### DESCRIPTION OF EXEMPLARY EMBODIMENTS

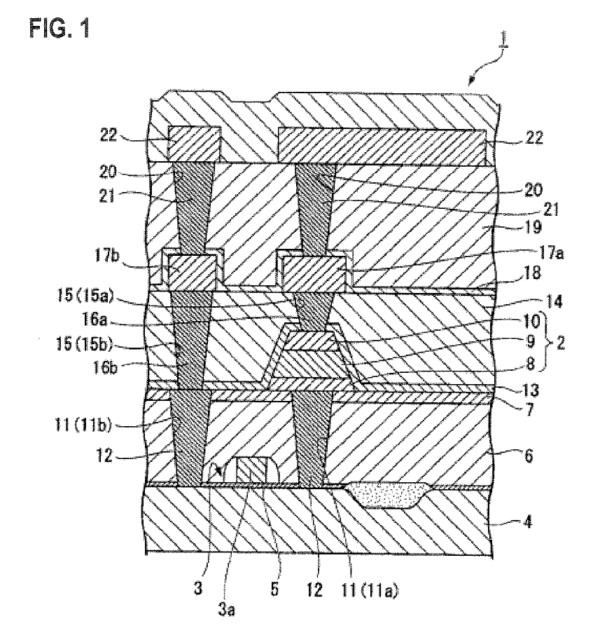

Preferred embodiments of the invention are described below in detail. Prior to describing a method for manufacturing a ferroelectric memory in accordance with an embodiment of the invention, an example of a ferroelectric memory in accordance with an embodiment of the invention is described. FIG. 1 is a cross-sectional view of a main portion of a ferroelectric memory in accordance with the embodiment of the invention. and the reference numeral 1 in FIG. 1 denotes the ferroelectric memory. The ferroelectric memory 1 is equipped with a ferroelectric capacitor 2, and a driving transistor 3 for operating the ferroelectric capacitor 2, wherein the driving transistor 3 is formed on a semiconductor substrate 4.

The semiconductor substrate 4 is composed of a silicon substrate, and has source/drain regions (not shown) and a channel region (not shown) formed in its surface section, and a gate dielectric film 5 formed on the channel region. Further, a gate electrode 3a is formed on the gate dielectric film 5, whereby the driving transistor 3 is formed on the semiconductor substrate 4. It is noted that the driving transistors 3 that correspond to the respective ferroelectric capacitors 2 are electrically isolated from one another by embedded isolation regions (not shown) formed in the semiconductor substrate 4.

Further, a first interlayer dielectric film 6 that covers the driving transistor 3 is formed on the semiconductor substrate 4, and a first hydrogen barrier film 7 is further formed on the first interlayer dielectric film 6. The first interlayer dielectric film 6 is composed of silicon oxide (Si0₂) and may be planarized by a CMP (chemical mechanical polishing) method or the like. Also, the first interlayer dielectric film 6 is formed with hydrogen concentration relatively higher than that of a second interlayer dielectric film on the ferroelectric capacitor 2 to be described below. The first hydrogen barrier film 7 may be composed of, for example, silicon nitride (SiN), and is provided to prevent hydrogen in the first interlayer dielectric film 6 from diffusing and penetrating in the ferroelectric capacitor 2 to be described below.

Further, the ferroelectric capacitor 2 is formed on the first hydrogen barrier film 7 that is formed on the first interlayer dielectric film 6 and covers the driving transistor 3. The ferroelectric capacitor 2 is a stacked type, and composed of a lower electrode 8 formed on the first hydrogen barrier film 7, a ferroelectric layer 9 formed on the lower electrode 8, and an upper electrode 10 formed on the ferroelectric layer 9. The lower electrode 8 and the upper electrode 10 may be formed with platinum (Pt), iridium (Ir), iridium oxide (IrO₂) or the like, and the ferroelectric layer 9 is formed with Pb(Zr, Ti)0₃ (PZT), (Pb, La) (Zr, Ti) O₃ (PLZT), or a material with metal such as niobium (Nb) or the like added to any of the aforementioned materials.

It is noted that a first contact hole 11 is formed in a manner to penetrate the first interlayer dielectric film 6 and the first hydrogen barrier film 7. The first contact hole 11 is embedded with a first plug 12 composed of tungsten (W) or the like. The first contact hole 11 in the present example is composed of a capacitor side contact hole 11a that connects to one of the source and drain regions of the driving transistor 3 and also connects to a bottom section of the lower electrode 8, and a wiring side contact hole 11b that connects to the other of the source and drain regions of the driving transistor 3 and also connects to a second plug to be described below.

The first plug 12 embedded in the capacitor side contact hole 11a having the structure described above conductively connects one of the source and drain regions of the driving transistor 3 to the lower electrode 8 of the ferroelectric capacitor 2. By this, the ferroelectric capacitor 2 is operated by the driving transistor 3, as described above. Also, the wiring side contact hole 11b conductively connects the other of the source and drain regions of the driving transistor 3 and the second plug.

Further, on the ferroelectric capacitor 2 is formed a second hydrogen barrier film 13 composed of Al₂0₃ or the like in a manner to cover its upper surface (i.e., the upper electrode 10) and its side surface. Because the ferroelectric capacitor 2 have the structure described above, diffusion and penetration of hydrogen in the ferroelectric capacitor 2 through its bottom side are prevented by the first hydrogen barrier film 7, and also diffusion and penetration of hydrogen in the ferroelectric capacitor 2 through its upper section and side section are prevented. It is noted that, in the present example, the second hydrogen barrier film 13 is also formed on the upper surface of the first hydrogen barrier film 7. However, the second hydrogen barrier film 13 may be patterned so as to cover mainly the upper surface and side surfaces of the ferroelectric capacitor 2 alone, and portions thereof in other areas on the first hydrogen barrier film 7 may be removed by etching.

In the manner, a second interlayer dielectric film 14 whose surface is planarized is formed on the second hydrogen barrier film 13, further covering the ferroelectric capacitor 2 that is covered by the second hydrogen barrier film 13. The second interlayer dielectric film 14 is formed with hydrogen concentration relatively lower than that of the first interlayer dielectric film 6 formed on the driving transistor 3, as described above.

A second contact hole 15 is formed in a manner to penetrate the second interlayer dielectric film 14 and the second hydrogen barrier film 13. The second contact hole 15 is embedded with a second plug 16a (16b) composed of tungsten (W) or the like. The second contact hole 15 in the present example is composed of a capacitor side contact hole 15a that connects to the upper electrode 10 of the ferroelectric capacitor 2, and a wiring side contact hole 15b that connects to the first plug 12 inside the wiring side contact hole 11b.

The second plug 16a embedded in the capacitor side contact hole 15a having the structure described above conductively connects to the upper electrode 10 of the ferroelectric capacitor 2, and the second plug 16b embedded in the wiring side contact hole 15b conductively connects to the other of the source and drain regions of the driving transistor 3 through the first plug 12.

Further, metal wirings 17a and 17b composed of aluminum (Al) that are connected to the second plugs 16a and 16b, respectively, are formed on the second interlayer dielectric film 15. Further, a third hydrogen barrier film 18 that covers the metal wirings 17a and 17b is formed on the second interlayer dielectric film 15. Also, a third interlayer dielectric film 19 is further formed on the third hydrogen barrier film 18, and third contact holes 20 and third plugs 21 are formed in the third interlayer dielectric film 19. Further, a metal wiring 22 is formed on the third interlayer dielectric film 19. A similar structure as the structure described above may be repeated further on, thereby forming a multilayered wiring structure.

Next, a method for manufacturing a ferroelectric memory 1 in accordance with an embodiment of the invention is described based on the method for manufacturing the ferroelectric memory 1 thus structured.

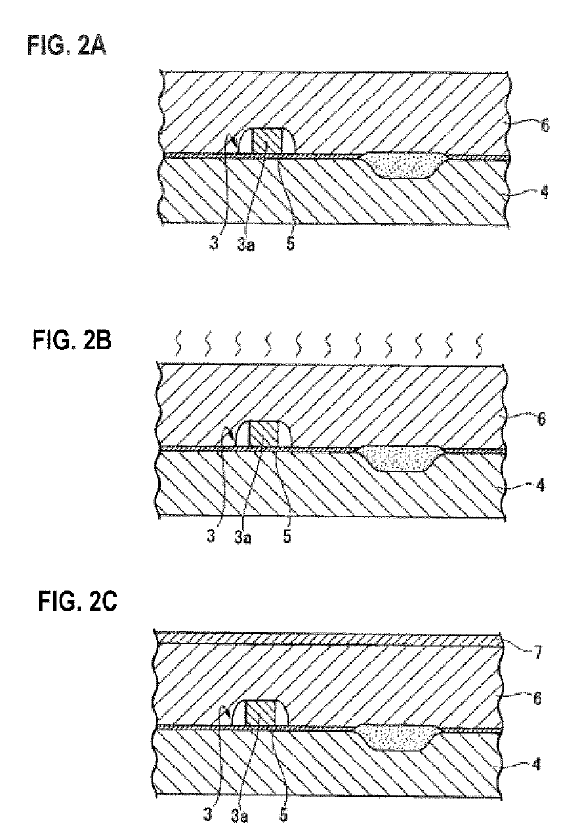

First, as shown in FIG. 2A, a driving transistor 3 is formed on a semiconductor substrate 4 by a known technology. Then, a silicon oxide (SiO₂) film that covers the driving transistor 3 is formed, and this film is further planarized by a chemical mechanical polishing (CMP) method or the like, thereby forming a first interlayer dielectric film 6. The SiO₂ film may be formed by a spin coat method, a CVD method such as a HDP (high density plasma) CVD method or the like. It is noted that, in order to increase hydrogen concentration of the first interlayer dielectric film 6 higher than that of a second interlayer dielectric film 14 to be formed in a later step, when a CVD method that uses, for example, silane (SiH₄) or tetraethoxysilane (TEOS) as the main raw material is used, its processing condition is appropriately set such that hydrogen generated by decomposition of the raw material can be abundantly taken into the film obtained.

(b) Next, as shown in FIG. 2B, heat treatment is applied to the semiconductor substrate 4 described above in an atmosphere containing hydrogen at 400° C. to 450° C., thereby conducting hydrogen sintering treatment. By conducting the treatment, hydrogen in the atmosphere diffuses in the first interlayer dielectric film 6, thereby exciting hydrogen existing in the first interlayer dielectric film 6, and the hydrogen acts on and diffuses in the gate dielectric film 5. As a result, defects in the gate dielectric film 5 are terminated, and its interface state is well stabilized (reduced). It is noted that the hydrogen sintering treatment is conducted prior to the step of forming a fist hydrogen barrier film 7 to be conducted later. Therefore, the hydrogen sintering treatment can be applied favorably to the gate dielectric film 5 of the driving transistor 3, without being influenced by the first hydrogen barrier film 7.

Next, as shown in FIG. 2C, a first hydrogen barrier film 7 composed of, for example, silicon nitride (SiN) is formed on the first interlayer dielectric film 6 by a CVD method or the like. By forming the first hydrogen barrier film 7 in this manner, even when hydrogen concentration of the first interlayer dielectric film 6 is high, the hydrogen in the first interlayer dielectric film 6 can be prevented from passing through the first hydrogen barrier film 7 and diffusing into an upper layer thereof.

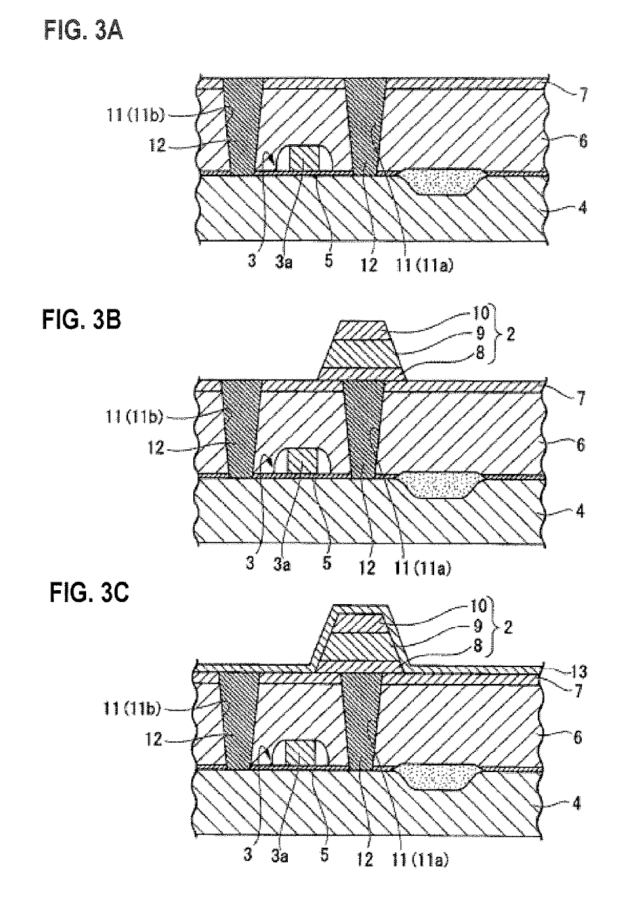

Then, a resist pattern (not shown) is formed on the first hydrogen barrier film 7 by a known method, and etching is conducted with the resist pattern as a mask, whereby the first hydrogen barrier film 7 and the first interlayer dielectric film 6 may be etched in a batch, or separately from one another, as shown in FIG. 3A, to form first contact holes 11 (11a, 11b). Then, after removing the resist pattern, a film of conductive material such as tungsten (W) is formed and embedded in the first contact holes 11, and portions of the conductive material film on the first hydrogen barrier film 7 are removed by a chemical mechanical polishing (CMP) method, thereby forming first plugs 12. For forming and embedding the film of conductive material, for example, layers of titanium (Ti) and titanium nitride (TiN) may be formed as an adhesion layer by a sputter method or the like, and then a layer of tungsten (W) may be formed.

Then, as shown in FIG. 3B, a ferroelectric capacitor 2 that is composed of a lower electrode 8, a ferroelectric layer 9 and an upper electrode 10 is formed on the first hydrogen barrier film 7 by a known technology. When the ferroelectric capacitor 2 is formed, positioning and patterning should be appropriately conducted such that the lower electrode 8 in particular is to be connected to the first plug 12 within the capacitor side contact hole 11a.

Then, as shown in FIG. 3C, a second hydrogen barrier film 13 composed of AlOₓ or the like that covers the ferroelectric capacitor 2 is formed. As a result, diffusion and penetration of hydrogen in the ferroelectric capacitor 2 through its bottom side are prevented by the first hydrogen barrier film 7 formed in advance, and also diffusion and penetration of hydrogen in the ferroelectric capacitor 2 from its upper side and side section side are prevented, such that the ferroelectric capacitor 2 becomes superior and resistant to hydrogen.

The second hydrogen barrier film 13 may preferably be formed to have a thickness between about 20 nm and about 100 nm. When the film thickness is less than 20 nm, the hydrogen barrier effect of the second hydrogen barrier film 13 may not be sufficiently obtained, and when the film thickness exceeds 100 nm, the load in etching for forming contact holes to be described below becomes great. Also, the first hydrogen barrier film 7 may preferably be formed also to have a thickness between about 20 nm and about 100 nm for the same reasons explained for the second hydrogen barrier film 13.

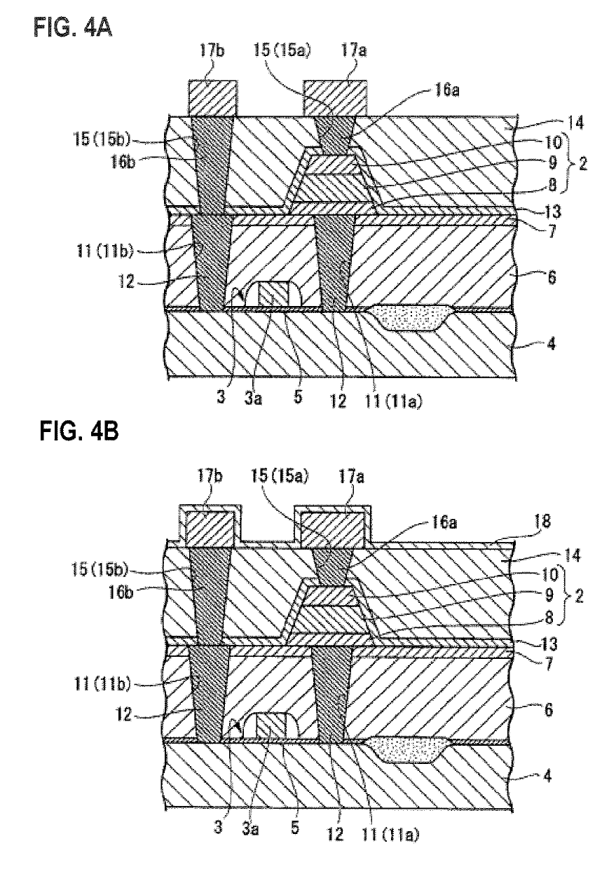

Next, as shown in FIG. 4A, a silicon oxide (SiO₂) film that covers the second hydrogen barrier film 13 is formed, and this film is planarized by a chemical mechanical polishing (CMP) method or the like, thereby forming a second interlayer dielectric film 14. A CVD method may preferably be used for forming the film of SiO₂. It is noted that, in order to lower hydrogen concentration of the second interlayer dielectric film 14 than that of the first interlayer dielectric film 6 formed in the preceding step, when a CVD method that uses, for example, silane (SiH₄) or tetraethoxysilane (TEOS) as the main raw material is used, its processing condition is set differently from the condition used in the step of forming the first interlayer dielectric film 6, such that hydrogen generated by decomposition of the raw material would hardly be taken into the film obtained. Also, anneal treatment may be conducted, if necessary, to thereby remove hydrogen from the second interlayer dielectric film 14.

Then, a resist pattern (not shown) is formed on the second interlayer dielectric film 14 by a known method, and etching is conducted with the resist pattern as a mask to thereby form second contact holes 15, i.e., a capacitor contact hole 15a that reaches the upper electrode 10 of the ferroelectric capacitor 2 and a wiring side contact hole 15b that connects to the first plug 12 in the wiring side contact hole 11b in the second interlayer dielectric film 14. Then, after removing the resist pattern, a film of conductive material is formed on the second interlayer dielectric film 14, whereby the conductive material is embedded in the second contact holes 15 (the capacitor contact hole 15a and the wiring side contact hole 15b). Film forming and embedding of the conductive material may be conducted in a manner similar to, for example, the case of the first plug 12. Then, by planarizing the upper surface of the first interlayer dielectric film 14 by a chemical mechanical polishing method or the like, thereby forming second plugs 16a and 16b in the second contact holes 15 (15a and 15b).

Then, a film of aluminum (Al) is formed on the second interlayer dielectric film 14 by a sputter method and the film is patterned by a known method, whereby metal wirings 17a (17b) that connect to the second plugs 16a (16b) are formed.

When the metal wirings 17a and 17b are formed in this manner, hydrogen sintering treatment is conducted to improve the condition of the interface between the metal wirings 17a and 17b and the second plugs 16a and 16b. The hydrogen sintering treatment may be conducted, for example, under similar conditions as those of the hydrogen sintering treatment conducted after the first interlayer dielectric film 6 has been formed.

By conducting the hydrogen sintering treatment in this manner, the condition of the interface between the metal wirings 17a and 17b and the second plugs 16a and 16b can be made excellent, and the contact resistance between them can be lowered. It is noted that, when the metal wirings 17a and 17b are formed with Al by a sputter method, the films formed by a sputter method do not have sufficient density. Also, when the film is formed by a sputter method, the obtained film and the second plugs 16a and 16b are merely in physical contact (physically bonded) with each other. By conducting heat treatment in the hydrogen sintering treatment, for example, at 400° C. to 450° C., the metal wirings 17a and 17b can be sintered and densified. Furthermore, the metal wirings 17a and 17b and the second plugs 16a and 16b are not only in physical contact (physically bonded), but also in chemical contact (chemically bonded) as the interfaces are activated. As a result, the contact resistance between the metal wirings 17a and 17b and the second plugs 16a and 16b can be sufficiently reduced. It is noted that heat treatment in an inert atmosphere may be adopted instead of the hydrogen sintering treatment conducted in this step. Even in this case, the hydrogen sintering treatment provides similar effects as those obtained by the hydrogen sintering treatment described above.

Then, as shown in FIG. 4B, a third hydrogen barrier film 18 that covers the metal wirings 17a and 17b is formed over the second interlayer dielectric film 14. The third hydrogen barrier film 18 may be formed with the above described material, such as, SiN or Al₂O₃. Then, a third interlayer dielectric film 19 is formed on the third hydrogen barrier film 18 as shown in FIG. 1, third contact holes 20 and third plugs 21 are formed in the third interlayer dielectric film 19, and metal wirings 22 are formed on the third interlayer dielectric film 19, whereby the ferroelectric memory 1 is obtained.

In the method for manufacturing the ferroelectric memory 1, hydrogen sintering treatment is conducted after the driving transistor 3 is formed, and prior to forming the first hydrogen barrier film 7, the hydrogen sintering treatment can be applied to the driving transistor 3 without being affected by the first hydrogen barrier film 7, such that the interface state of the gate oxide film 5 can be favorably stabilized (reduced). Also, because the first hydrogen barrier film 7 is formed on the bottom side of the ferroelectric capacitor 2, hydrogen can be prevented from diffusing and penetrating through the bottom side of the ferroelectric capacitor 2. Also, the second hydrogen barrier film 13 that covers the ferroelectric capacitor 2 is formed such that diffusion and penetration of hydrogen through the upper section side and the side section side can be prevented. Therefore, the resistance of the ferroelectric capacitor 2 against hydrogen can be sufficiently increased.

Moreover, as described above, the interface state of the gate dielectric film 5 of the driving transistor 3 is stabilized (reduced), and the resistance of the ferroelectric capacitor 2 against hydrogen is sufficiently increased, such that the ferroelectric memory 1 thus obtained becomes to be superior and highly reliable.

The ferroelectric memories described above are applicable to a variety of electronic devices, such as, cellular phones, personal computers, liquid crystal devices, electronic note pads, pagers, POS terminals, IC cards, mini disk players, liquid crystal projectors, engineering work stations (EWS), word processors, television sets, view-finder type or monitor direct-view type video tape recorders, electronic desk-top calculators, car navigation devices, devices equipped with touch panels, watches, gaming devices, electrophoresis devices, and the like.

It is noted that the invention is not limited to the embodiment described above, and a variety of modifications can be made without departing from the subject matter of the invention. For example, in the embodiment, hydrogen sintering treatment is applied to the gate dielectric film 5 of the driving transistor 3 after the first interlayer dielectric film 6 is formed, but the hydrogen sintering treatment may be conducted before the first interlayer dielectric film 6 is formed. Even by so doing, the hydrogen sintering treatment would be conducted prior to the later step of forming the first hydrogen barrier film 7, such that the first hydrogen barrier film 7 cannot affect the hydrogen sintering treatment.

What is claimed is:

1. A method for manufacturing a ferroelectric memory, the method comprising the steps of:
forming a driving transistor on a semiconductor substrate;
forming a first interlayer dielectric film that covers the driving transistor on the semiconductor substrate;
forming a first hydrogen barrier film on the first interlayer dielectric film; and
forming a ferroelectric capacitor electrically connected to the driving transistor on the first hydrogen barrier film,
wherein hydrogen sintering treatment is conducted between the step of forming the driving transistor and the step of forming the first hydrogen barrier film.

2. A method for forming a ferroelectric memory according to claim 1, wherein the hydrogen sintering treatment is conducted after the step of forming the first interlayer dielectric film.

3. A method for manufacturing a ferroelectric memory according to claim 1, further comprising, after the step of forming the ferroelectric capacitor, the steps of:
forming a second hydrogen barrier film that covers the ferroelectric capacitor;
forming a second interlayer dielectric film on the second hydrogen barrier film;
forming, on the second interlayer dielectric film, a wiring that conductively connects to the ferroelectric capacitor through a plug; and
conducting hydrogen sintering treatment after the step of forming the wiring.

4. A method for manufacturing a ferroelectric memory according to claim 1, further comprising, after the step of forming the ferroelectric capacitor, the step of forming a second interlayer dielectric film that covers the ferroelectric capacitor and has a hydrogen concentration lower than a hydrogen concentration of the first interlayer dielectric film.
